(19) United States
(12) Patent Application Publication
(10) Pub. No.: US 2005/0174136 A1
(43) Pub. Date: Aug. 11, 2005

(54) Test pin back surface in probe apparatus for low wear multiple contacting with conductive elastomer

(76) Inventors: Jiachun Zhou, Fremont, CA (US); January Kister, Portola Valley, CA (US)

Correspondence Address: RATNERPRESTIA, P O BOX 980, VALLEY FORGE, PA, 19482-0980, US

(21) Appl. No.: 10/775,828

(22) Filed: Feb. 9, 2004

(51) Int. Cl. G01R 31/02

(52) U.S. Cl. 324/761

(57) ABSTRACT

A probe apparatus for preferably testing packaged circuit chips combines an ACE with plunger pins placed in between the ACE and the test contact. A plunger pin provides a contact end for contacting the test contacts and a back end configured for indenting the ACE. The contact end may be configured in conjunction with the test contacts particularities whereas the plunger pins' back ends have a curvature that corresponds to the ACE's deformation behavior in the impinging vicinity such wear relevant ACE deformations are kept to a minimum. The plunger pins are arrayed in a removable frame. For contacting ball grid arrays, the plunger pins feature on their front ends self centering interacting concentrically arrayed crown peaks.

### FIELD OF INVENTION

The present invention relates to contact interfaces of electrical contact pins with conductive elastomer. More particular, the present invention relates to electrical test pin back end shaped for low wear multiple contacting with conductive elastomer in a probe apparatus.

### BACKGROUND OF INVENTION

An anisotropic conductive elastomer (ACE) is a favorable structure for applications where a large number of independent electrically conductive and mechanically resilient paths need to be two dimensionally arrayed for contacting tightly arrayed contacts. As the miniaturization of circuit chips advances, ACEs are increasingly utilized in between the circuit chip and peripheral devices. In the field of circuit chip testing, ACEs are attractive structural elements that may assist in reducing a probe apparatus' complexity.

Commercially available ACEs may be configured with a number of substantially evenly and parallel arrayed metal filaments extending between two opposite access planes. The traces are resiliently held in position by an elastic material such as silicon rubber. The ACE may establish conductive connection between oppositely facing contacts of mirrored contact arrays.

The use of ACEs in a chip test apparatus poses particular challenges related to the high numbers of temporary contacting that have to be performed with minimum degradation of path resistance and structural wear of the ACE. In well known applications in which the ACE is directly contacted with the test contacts, the repeated contacting causes debris to form on the ACE surface. Due to the substantially closed surface configuration of the ACE, the debris is depositing in the direct vicinity of the filament ends and may compromise the contact quality in the interface at a relatively early stage compared to other well known probe designs. Cleansing the ACE from debris is unfortunately problematic since it requires the use of chemicals that may alter the ACE's physical properties or otherwise harm the filler material. In addition, the chemicals may be difficult to remove from an eventually sponge like ACE configuration. Therefore, there exists a need for a probe apparatus capable of utilizing an ACE without risk of debris at the ACE surfaces and without need for cleansing the ACE. The present invention addresses this need.

Another challenge in the use of ACE for multiple contacting is mechanical wear of the ACE structure. Particularly in the vicinity of repetitively impinging rigid contacting structures, the ACE may suffer increased wear due to excessive local deformation and/or stress of the filament as well as the elastic filler material. Therefore, there exists a need for an ACE multiplicatively indenting structures and a probe apparatus configured for minimizing wear of the ACE. The present invention addresses also this need.

### SUMMARY OF INVENTION

A probe apparatus for preferably testing packaged circuit chips combines an ACE with plunger pins placed in between the ACE and the test contact. A plunger pin provides a front end for contacting the chips' test contacts and a back end configured for impinging the ACE. The contact end may be configured in conjunction with the test contacts particularities whereas the plunger pins' back ends are specifically configured for minimizing ACE wear and contact resistance degradation. The plunger pins are arrayed and slide ably held in a carrier frame that may be readily removed for cleansing. The plunger pins have guiding portions that correspond to guide perforations in the carrier frame. The plunger pins feature also a central recess that corresponds to a snap feature in the frame to prevent the plunger pins from falling out during the cleansing operation.

The back surfaces have a curvature such that for a given indentation depth of the back surface into the ACE, the ACE's relevant deformation in the indentation vicinity remains on an overall minimum. Relevant deformation in the indentation vicinity may include but is not limited to surface shear between the back surface and ACE, tensile surface stress of the ACE surface, angular ACE surface displacement and deformation gradient in the ACE's indenting vicinity.

### BRIEF DESCRIPTION OF THE FIGURES

FIG. 1 is a front view of an assembled simplified exemplary probe apparatus while testing an exemplary packaged circuit chip.

FIG. 2 is a frontal exploded view of the probe apparatus of FIG. 1.

FIG. 3 is a perspective exploded view of the probe apparatus of FIG. 1.

FIG. 4 is a section view of the probe apparatus of FIG. 1.

FIG. 5 is a view of a detail encircled and labeled “A” in FIG. 4.

FIG. 6 shows a first exemplary plunger pin.

FIG. 7 depicts a second exemplary plunger pin.

FIG. 8 is an exemplary experimentally determined graph illustrating the relation of indentation opposing force and indentation depth of the first exemplary plunger pin experimentally fabricated and tested in combination with a commercially available anisotropic conductive elastomer (ACE).

### DETAILED DESCRIPTION

In the following the terms “horizontal, vertical, upwards, downwards, bottom, top, above, below” are used in conjunction with the Figures. As it may be clear to anyone skilled in the art, these terms are used solely for the purpose of ease of understanding and to describe spatial relations of elements with respect to each other.

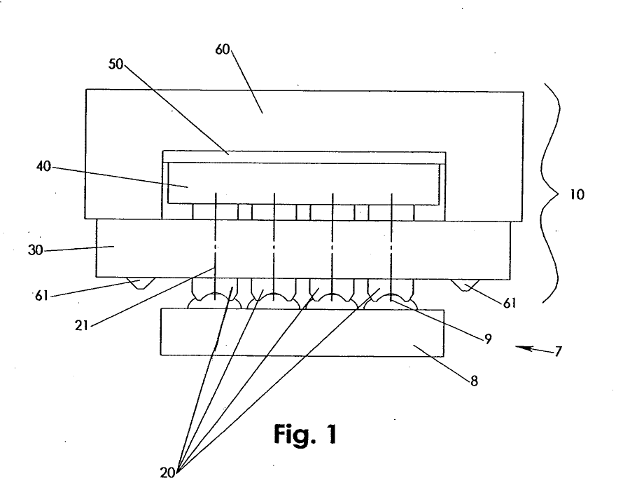

As in FIG. 1, a probe apparatus 10 may be configured for multiple testing of electronic circuitry 7, which is preferably in a well known packaged condition with device terminals 9 being accessible on a surface of the package 8. The probe apparatus 10 features plunger pins 20, each having a center axis 21 that is substantially parallel to an impinging direction of plunger pins 20 onto the device terminals 9.

The plunger pins 20 are embedded in a carrier frame 30 and moveable along their respective center axes 21. The carrier frame 30 in turn is attached to an apparatus housing 60 with frame fixtures 61, which provide precise positioning of the carrier frame 30 and consequently the plunger pins 20. The frame fixtures 61 may be optionally configured to be readily removed from and an reattached at the carrier frame 30 as may be well appreciated by anyone skilled in the art. In that fashion, the plunger pins 20 may be easily handled for cleansing operations during which debris may be removed from the plunger pins 20. Debris may form on and/or in the vicinity of the plunger pins 20 during eventual repetitive scribing of the plunger pins 20 on the device terminals 9 as is well known in the art.

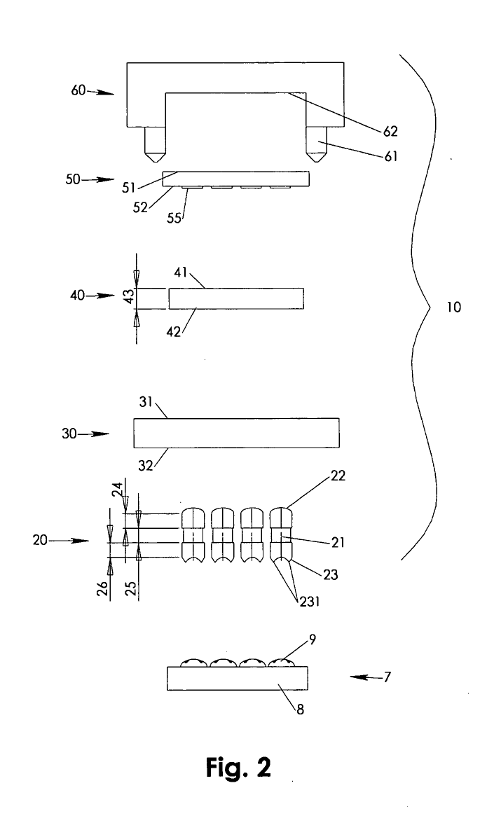

The apparatus housing 60 further holds a contact terminal 50 in the preferred configuration of a well known printed circuit board (PCB). Sandwiched between the PCB 50 and the plunger pins 20 is an anisotropic conductive elastomer (ACE) 40 well known in the art for providing insulated conductive paths within an elastic structure. The present invention includes embodiments in which the contact terminal 50 may be any well known separate or integral structure of the probe apparatus 10 that provide base contacts 55 (see FIGS. 2-4) in a useful fashion as described in the below.

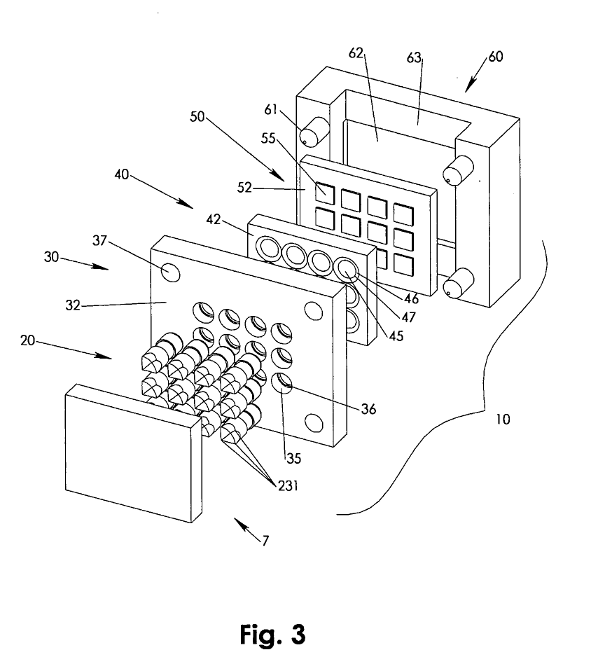

In FIGS. 2, 3, the probe apparatus 10 is illustrated in exploded view. The plunger pins 20 in a first basic configuration feature back surfaces 22 and front ends 23 with a number of crown peaks 231 substantially rotationally symmetric arrayed with respect to their center axes 21. Particularly in combination with device terminals 9 configured as well known ball grid array, the concentric crown peaks 231 provide for a self centering effect that prevents undesirable lateral forces resulting from an eventual slight out of center contacting of the pin front ends 23 with ball grid terminals 9. The present invention includes embodiments in which the front end 23 has any other well known configuration suitable for low resistive contacting of varied shaped device terminals 9.

The plunger pins 20 are preferably configured to be slide ably guided in a limited fashion along their respective center axes 21. For that purpose, the plunger pins 20 feature guide sections 24, 26 extending along their respective center axes 21. The guide sections 24, 26 correspond to guiding perforations 35 that extend between the frame top 31 and the frame bottom 32. The plunger pins 20 further feature recess sections 25 that correspond to retention flanges 36 inside the guiding perforations 35.

The carrier frame 30 is preferably a planar structure having a frame top 31 and a frame bottom 32 where the guiding perforation 35 may be fabricated from one or both sides such that the retention flange 36 is either in the middle of the guiding perforation 35 or at one of frame top 31 and frame bottom 32. The carrier frame 30 further features fixture fits 37 that correspond to the frame fixtures 61 as may be well appreciated by anyone skilled in the art.

The ACE 40 provides on one hand an insulated opposing force via the pin back surfaces 22 and the pin front ends 23 onto the device terminals 9 as result of a relative motion of the probe apparatus 10 towards the test chip 7 along the impinging direction. The relative motion eventually results in a penetration depth by which the pin front ends 23 scribe and sink into their opposing device terminals 9 and an indentation depth PD (see FIG. 5) by which the pin back surfaces 22 are forced into the resiliently deflecting ACE bottom 42 where it produces a temporary indentation 45.

Simultaneously to providing the impinging opposing force, the ACE 40 contributes to establishing insulated conductive paths between the pin front ends 23 and the base contacts 55. As the pin back surfaces 22 temporarily indent the ACE bottom 42 during one of many chip 7 testing cycles, the ACE 40 is held in position via the PCB bottom 52 pressing against the ACE top 41. The PCB base contacts 55 indent thereby the ACE top 21. Due to the indentation on both sides of the ACE 40 low resistive and insulated conductive connections are established between respective pin back surfaces 23 and base contacts 55 via conductive filaments arrayed and parallel extending between the ACE top 41 and ACE bottom 42 as is well known in the art.

Positions of base contacts 55 with respect to the center axes 21 are defined in correspondence with the spatial orientation of the conductive filament extending between the ACE top 41 and the ACE bottom 42. For example, an ACE 40 may be fabricated with perpendicular extending conductive filament in which case the base contacts 55 may be aligned and centered with their respective plunger pins' 20 center axes 21. In another example where an ACE 40 may be fabricated with angular extending conductive filaments, the base contacts 55 may be in an offset to their respective plunger pins' 20 center axes 21 that corresponds to the offset of the angular filaments' ends.

ACE 40 with angular filaments may be preferably utilized due to its eventual improved filament deflection within the ACE structure resulting from a pin indentation. An exemplary ACE 40 may have gold plated metal filaments with a pitch of about 0.1 mm and an offset of the opposing filament ends of about 0.5 mm for an ACE height 43 of about 1 mm.

PCB 50 and ACE 40 are substantially fixedly held within receptacle features 62, 63 such that the contact between base contacts 55 and ACE top is preferably substantially permanent. In addition, the base contacts 55 may eventually extend only slightly below the PCB bottom 52 such that the ACE top 41 may support itself additionally directly against the PCB bottom 52 during indentation of the pin back surfaces 22. Thus, substantial repetitive dynamic deformation is mainly observable in the vicinity of the pin indentations 45 and eventual transition curvatures 46.

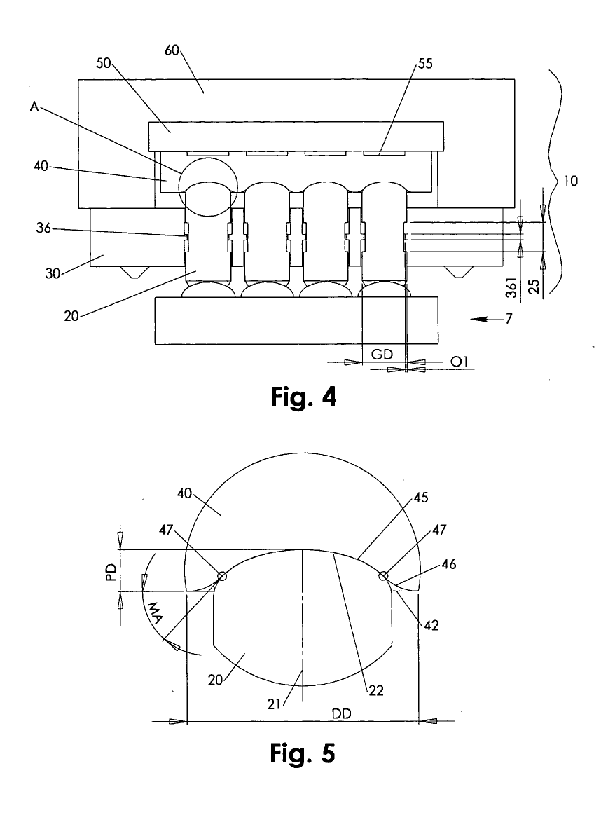

In the cross section view of FIG. 4 the retention flange 36 is shown with a height 361. The limits along which the plunger pins 20 are slide able are defined by the finite length of the recess section 25 minus the height 361 of the retention flange. During assembly insertion of the plunger pins 20 into the guiding perforation 35, the retention flange is non destructively and resiliently deformed. This is accomplished by having the carrier frame of a sufficiently elastic material composition selected in combination with the offset O1 between retention flange 36 and guide circumference GD. In an exemplary embodiment, the guide circumference GD may be a circular diameter of about 0.4 mm.

FIG. 5 is an enlarged detailed view of the pin indenting vicinity in an ACE 40 where relevant deformations take place. Relevant deformations may include but are not limited to surface shear along the contact boundary 47 between the back surface and ACE, tensile surface stress of the ACE bottom 42, angular ACE surface displacement and deformation gradient in the ACE 40 structure in the vicinity of pin indentations 45 and transition curvatures 46. Dependent on the ACE's 40 deformation behavior the transition curvature 46 may vary. In cases where the ACE 40 has a substantially integer surface layer with a tensile strength and/or stiffness larger than the ACE's 40 core structure, the transition curvature 46 may increase correspondingly and as may be well appreciated by anyone skilled in the art.

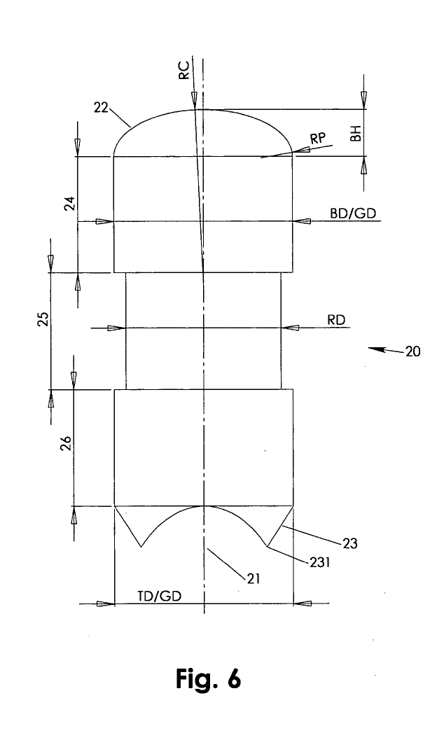

Referring also to FIG. 6, relevant deformations are brought in one aspect to a minimum by providing the back surface 22 with a curvature that is rotationally symmetric with respect to the center axis 21 and that is continuous at least within the pin indentation area 45. The back surface 22 has a center radius RC that is at a maximum in proximity of the center axis 21 and decreases towards a back circumference BD where it transforms into peripheral radius RP. In a simplified embodiment, the curvature center radius RC is infinite. The back surface 22 may be also defined by the center radius RC and the peripheral radius RP alone. The height BH of the back surface 22 may be defined at least equal with the indentation depth PD. The continuous curvature of the back surface 23 minimized the deformation gradient in the structural body of the ACE 40 immediately adjacent the indentation area 45. The deformation gradient is the rate at which deformation changes within a structure.

Another aspect in minimizing relevant deformations is selecting the curvature of the back surface 22 such that bending stress and eventual sheer stress between the ACE's 40 bottom surface and the back surface 22 is substantially eliminated along the contact boundary 47. This is accomplished in the present invention by defining the back surface 22 additionally such that it is substantially tangential with the ACE's 40 bottom surface along the contact boundary 47 at least at a maximum indentation depth PD where ACE's 40 strain in the indentation vicinity is at a maximum. This means that along the contact boundary 47, the back surface 22 and the ACE's 40 bottom surface share a common tangent angle MA.

As may be well appreciated by anyone skilled in the art, the deformation gradient may be at a minimum in the indentation vicinity of the ACE 40 structure where the smallest surface curvature of the indentation area 45 and eventual transition curvature 46 are kept to a maximum. This would mean for the sole purpose of minimizing deformation gradient in the ACE 40 structure, indentation area 45 curvature and transition curvature 46 would be equally brought to a maximum by maximizing surface strength and surface stiffness of the ACE bottom 42 surface.

Unfortunately this would also increase the overall deformation circumference DD. In a practical case of tightly spaced device terminals 9, the deformation circumference DD may not be larger than a minimum pitch of the device terminals 9 to secure insulated opposing forces onto each plunger pin 20 as may be well appreciated by anyone skilled in the art.

The present invention best balances the need to keep the overall circumference DD below maximum device terminal 9 pitch while keeping the deformation gradient to a minimum by defining the back surface 22 at one hand with continuous curvature that is at a maximum at the center axis 21 and decreases in direction away from the center axis 21 and on the other hand such that the back surface 22 shares a common tangent angle MA with the ACE's 40 bottom surface at least along the contact boundary 47. In that way, surface shear between the back surface 22 and ACE 40 as well as tensile surface stress of the ACE bottom 42 surface are also kept to a feasible minimum.

Another concern in shaping the back surface 22 is the interaction of the back surface 22 with metal filaments that also deflect during indentation. To minimize the risk of plastic lateral deformation of the filaments due to excessive lateral filament deviation within the ACE 40, the overall angular displacement in the indentation area 45 is preferably kept to a minimum. The embodiments of the present invention comply with this identified requirement.

In another embodiment, the back surface 22 may have a curvature defined such that tangency with the ACE's 40 bottom surface is substantially maintained during the indentation process where the contact boundary 47 gradually increases between zero diameter at indentation begin up to maximum contact boundary 47 diameter at maximum indentation depth PD. An ellipsoidal back surface 22 may comply with this identified requirement. The ellipsoidal back surface 22 may have a cross section in which the short axis of the ellipse contour substantially coincides with the center axis 21.

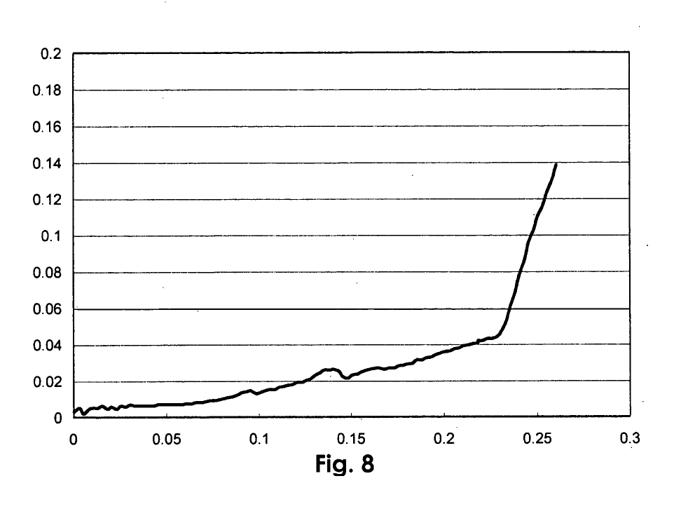

In a further embodiment, the back surface 22 may have a curvature defined such that the contact boundary 47 gradually increased/decreases between zero diameter at indentation begin/end up to maximum contact boundary 47 diameter at maximum indentation depth PD. The ellipsoidal back surface 22 may comply with this identified requirement. In that fashion, the relation of opposing force and indentation depth may be adjusted as exemplarily depicted in FIG. 8 where the horizontal axis shows indentation depth in mm and the vertical axis shows opposing force in kp. The graph of FIG. 8 was experimentally obtained from an plunger pin having a back circumference BD of about 0.4 mm, an infinite center radius RC directly transforming into a peripheral radius of about 0.15 mm. The center radius RC has a radial extension of about 0.05 mm off the center axis 21. Preferred indentation depth PD is about 0.15 mm resulting in an opposing force of about 20 g for an ACE 40.

The ellipsoidal back surface 22 is relatively simple defined for fabrication purposes and providing continuously outward decreasing curvature radius that provides during indentation progress for common tangent angle MA, continuously increasing contact boundary 47, minimal overall angular ACE 40 surface deflection and feasible deflection gradient.

In further embodiment, the back surface 22 may seamlessly transition into the back circumference BD avoiding excess pressure on the contact boundary 47 in cases where the indentation depth PD exceeds the back surface height BH.

The exemplary plunger pin 20 of FIG. 6 has two guide sections 24, 26 immediately adjacent the back surface 22 and the front end 23. The recess section 25 is placed in between. Front circumference TD and back circumference BD are the same time guide circumference GD. In this embodiment, the contact boundary 47 may be slightly less than the back and front circumferences BD, TD.

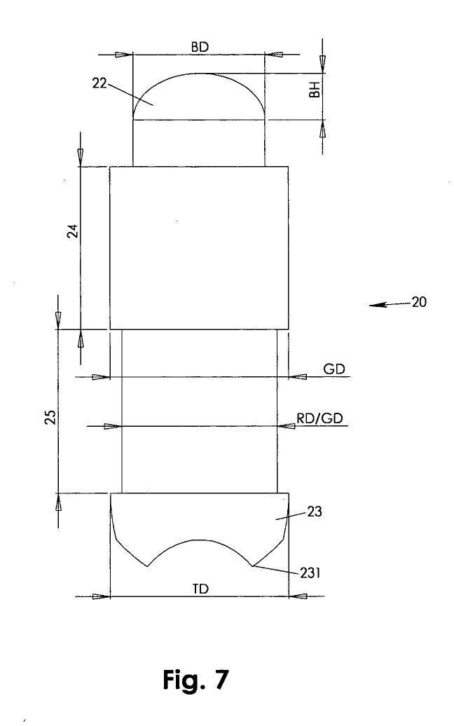

The opposing force maximum may be adjusted by independently scaling the back surface 22 such that the back circumference BD is independent from the guide circumference GD. Especially with increasingly large numbers of plunger pins 20 arrayed within the probe apparatus 10 for simultaneous contacting, the opposing force may reduced to keep the overall forces in the probe apparatus 10 within feasible ranges as may be well appreciated by anyone skilled in the art. FIG. 7 depicts an exemplary plunger pin 20 having a reduced back circumference BD. In addition, the plunger pin 20 of FIG. 7 utilizes only a single guide section 24 with the recess section 25 being placed immediately adjacent the front end 23. The recess section 25 may be thereby utilized as guiding section as well. A corresponding retention flange 36 may be placed at the frame bottom 32. The offset between the front end 23 and the recess circumference RD may assist in preventing scribing debris to enter the guiding perforation 35.

The present invention includes embodiments in which the retention flange 36 may be fabricated of a separate material layer specifically configured for elasticity and sealing.

Accordingly, the scope of the invention described in the specification above is set forth by the following claims and their legal equivalence:

1. An ACE multiplicatively indenting plunger pin comprising:
a. a center axis substantially parallel with an impinging direction of said plunger pin;
b. a back surface substantially rotationally symmetric with respect to said center axis, said back surface having a continuous curvature that is at a maximum radius in proximity of said center axis and decreases towards a back circumference of said plunger pin.

2. The ACE multiplicatively indenting plunger pin of claim 1, wherein said back surface seamlessly transitions into said back circumference.

3. The ACE multiplicatively indenting plunger pin of claim 1, wherein said back surface has a surface height that is at least equal to an indenting depth of said back surface in said ACE.

4. The ACE multiplicatively indenting plunger pin of claim 1, wherein said maximum radius is infinite.

5. The ACE multiplicatively indenting plunger pin of claim 1, wherein said back surface is an ellipsoid with a short axis of said ellipsoid's central cross section substantially coincides with said center axis.

6. The ACE multiplicatively indenting plunger pin of claim 1, further comprising a guide section extending along said center axis.

7. The ACE multiplicatively indenting plunger pin of claim 6, wherein said back circumference is independent of a guide circumference of said guide section.

8. The ACE multiplicatively indenting plunger pin of claim 1, further comprising a recess section having a finite length along said center axis, said recess section having a recess circumference that is offset from said guide circumference in direction towards said center axis.

9. The ACE multiplicatively indenting plunger pin of claim 6 slide ably held in a guiding perforation of a carrier frame, said guiding perforation being correspondingly shaped with said guide section such that said plunger pin slides in a guided fashion along said center axis.

10. The ACE multiplicatively indenting plunger pin of claim 9, further comprising a recess section having a finite length along said center axis, said recess section having a recess circumference that is offset from said guide circumference in direction towards said center axis and wherein said guiding perforation further comprises a retention flange corresponding to said recess section such that said plunger pin is slide able within limits defined by the recess section minus a height of said retention flange.

11. The ACE multiplicatively indenting plunger pin of claim 10, wherein said carrier frame is of a material composition and said retention flange is in an offset from said guide circumference towards said center axis such that said retention flange may be non destructively resiliently deformed during assembly insertion of said plunger pin into said guiding perforation.

12. The ACE multiplicatively indenting plunger pin of claim 1, further comprising a pin front end having a number of crown peaks substantially rotationally symmetric arrayed with respect to said center axis.

13. A multiple testing probe apparatus comprising:
a. a base contact;
b. an ACE having a top and a bottom, wherein said top is in conductive contact with said base contact;
c. a carrier frame having a guiding means extending between a top and a bottom of said carrier frame, said frame top being immediately adjacent to said ACE bottom; and
d. a plunger pin for transmitting an electrical current, said plunger pin having:
a. a center axis substantially parallel with an impinging direction of said plunger pin and substantially aligned with said guiding means;
b. a back surface substantially rotationally symmetric with respect to said center axis, said back surface having a continuous curvature that is at a maximum radius in proximity of said center axis and decreases towards a back circumference of said plunger pin such that for a given indenting depth of said back surface into said ACE bottom a relevant deformation in an impinging vicinity of said ACE remains on an overall minimum, said impinging vicinity being immediately adjacent to said impinging back surface;
c. a guiding feature corresponding to said guiding means such that said plunger pin is moveable along said center axis at least up to said indenting depth; and
d. an electrically conductive pin front end such that an insulated conductive path is established between said pin front end and said base contact and such that simultaneously an opposing force is exerted from said ACE via said back surface onto said plunger pin while said plunger pin is displaced in one of multiple displacements with said indenting depth along said center axis in direction of said ACE.

14. The probe apparatus of claim 13, wherein said back surface seamlessly transitions into said back circumference.

15. The probe apparatus of claim 13, wherein said back surface has a surface height that is at least equal to said indenting depth.

16. The probe apparatus of claim 13, wherein said maximum radius is infinite.

17. The probe apparatus of claim 13, wherein said back surface is an ellipsoid with a short axis of said ellipsoid's central cross section substantially coincides with said center axis.

18. The probe apparatus of claim 13, wherein said guiding feature is a guide section extending along said center axis.

19. The probe apparatus of claim 18, wherein
said back circumference is independent of a guide circumference of said guide section.

20. The probe apparatus of claim 18, wherein said guiding feature is a guiding perforation correspondingly shaped with said guide section such that said plunger pin slides in a guided fashion along said center axis.

21. The probe apparatus of claim 20, wherein said plunger pin further comprising a recess section having a finite length along said center axis, said recess section having a recess circumference that is offset from said guide circumference in direction towards said center axis and wherein said guiding perforation further comprises a retention flange corresponding to said recess section such that said plunger pin is slide able within limits defined by the recess section minus a height of said retention flange, said limits being at least equal to said indenting depth.

22. The probe apparatus of claim 21, wherein said carrier frame is of a material composition and said retention flange is in an offset from said guide circumference towards said center axis such that said retention flange may be non destructively resiliently deformed during assembly insertion of said plunger pin into said guiding perforation.

23. The probe apparatus of claim 13, wherein said pin front end has a number of crown peaks substantially rotationally symmetric arrayed with respect to said center axis.
